(19) United States
(12) Patent Application Publication
(10) Pub. No.: US 2023/0411523 A1
(43) Pub. Date: Dec. 21, 2023

(54) VERTICAL FIELD EFFECT TRANSISTOR WITH STRAINED CHANNEL

(71) Applicant: International Business Machines Corporation, Armonk, NY (US)

(72) Inventors: Shogo Mochizuki, Mechanicville, NY (US); Juntao Li, Cohoes, NY (US); Kangguo Cheng, Schenectady, NY (US)

(21) Appl. No.: 17/807,011

(22) Filed: Jun. 15, 2022

(51) Int. Cl. H01L 29/78; H01L 29/06; H01L 29/66

(52) U.S. Cl. CPC H01L 29/7842; H01L 29/66795; H01L 29/0649

(57) ABSTRACT

A vertical field effect transistor with a strained channel includes a channel fin structure extending vertically from a substrate. The channel fin structure being composed of a stress liner embedded within a semiconductor channel layer. The stress liner induces an uniaxial strain along a vertical direction of the channel fin structure. A high-k material is disposed along sidewalls of the semiconductor channel layer followed by a workfunction metal and a gate material. A top source/drain region is located above a top portion of the channel fin structure, and a bottom source/drain region, formed within the substrate, is located adjacent to a bottom portion of the channel fin structure.

### BACKGROUND

The present invention generally relates to the field of semiconductor devices, and more particularly to vertical field effect transistors (VFETs).

Field effect transistors (FETs) are typically formed on semiconductor substrates and include a channel region disposed between source and drain regions, and a gate configured to electrically connect the source and drain regions through the channel region. Structures where the channel region is parallel to the main surface of the substrate are referred to as planar FET structures, while structures where the channel region is perpendicular to the main surface of the substrate are referred to as vertical FETs (VFETs). Thus, in a VFET device the direction of the current flow between the source and drain regions is normal (perpendicular) to the main surface of the substrate.

A typical VFET device includes a vertical fin or nanowire that extends upward from the substrate. The fin or nanowire forms the channel region of the transistor. A source region and a drain region are situated in electrical contact with the top and bottom ends of the channel region, while the gate is disposed on one or more of the fin or nanowire sidewalls. In general, it has been found that inducing strain in the channel region of a transistor is useful to improve carrier mobility and device performance. However, due to VFETs structural challenges it can be difficult to induce strain in the channel region along a vertical direction.

### SUMMARY

According to an embodiment of the present disclosure, a semiconductor structure includes a channel fin structure extending vertically from a substrate, the channel fin structure being composed of a stress liner embedded within a semiconductor channel layer for inducing an uniaxial strain along a vertical direction of the channel fin structure, a high-k material disposed along sidewalls of the semiconductor channel layer, a workfunction metal disposed above the high-k material, and a gate material disposed above the workfunction metal. In some embodiments, the stress liner includes a compressive stressed silicon nitride material for providing a tensile strain on the channel fin structure. In other embodiments, the stress liner includes a tensile stressed silicon nitride material for providing a compressive strain on the channel fin structure.

According to another embodiment of the present disclosure, a method of forming a semiconductor structure includes forming a channel fin structure extending vertically from a substrate, the channel fin structure including a stress liner surrounded by a semiconductor channel layer for inducing an uniaxial strain along a vertical direction of the channel fin structure, forming a high-k material disposed along sidewalls of the semiconductor channel layer, forming a workfunction metal disposed above the high-k material, and forming a gate material disposed above the workfunction metal. In some embodiments, the stress liner includes a compressive stressed silicon nitride material for providing a tensile strain on the channel fin structure. In other embodiments, the stress liner includes a tensile stressed silicon nitride material for providing a compressive strain on the channel fin structure.

### BRIEF DESCRIPTION OF THE DRAWINGS

The following detailed description, given by way of example and not intended to limit the invention solely thereto, will best be appreciated in conjunction with the accompanying drawings, in which:

FIG. 1 is a cross-sectional view of a semiconductor structure at an intermediate step during a semiconductor manufacturing process, according to an embodiment of the present disclosure;

FIG. 2 is a cross-sectional views of the semiconductor structure after forming and patterning a hardmask layer, according to an embodiment of the present disclosure;

FIG. 3 is a cross-sectional view of the semiconductor structure after patterning sacrificial channel fins, according to an embodiment of the present disclosure;

FIG. 4 is a cross-sectional view of the semiconductor structure after trimming the sacrificial channel fins, according to an embodiment of the present disclosure;

FIG. 5 is a cross-sectional view of the semiconductor structure after forming a semiconductor channel layer along sidewalls of the sacrificial channel fins, according to an embodiment of the present disclosure;

FIG. 6 is a cross-sectional view of the semiconductor structure after forming a sacrificial fin spacer and bottom source/drain regions, according to an embodiment of the present disclosure;

FIG. 7 is a cross-sectional view of the semiconductor structure after forming a bottom spacer, a high-k material, a workfunction metal, a gate material and a top spacer, according to an embodiment of the present disclosure;

FIG. 8 is a cross-sectional view of the semiconductor structure after removing the hardmask layer and the sacrificial channel fins, according to an embodiment of the present disclosure;

FIG. 9 is a cross-sectional view of the semiconductor structure after depositing a stress liner, according to an embodiment of the present disclosure;

FIG. 10 is a cross-sectional view of the semiconductor structure after conducting an etch-back process on the stress liner, according to an embodiment of the present disclosure;

FIG. 11 is a cross-sectional view of the semiconductor structure after forming top source/drain regions and metal contacts, according to an embodiment of the present disclosure;

FIG. 11A depicts a compressive stressed liner for forming a tensile strained channel, according to an embodiment of the present disclosure; and

FIG. 11B depicts a tensile stressed liner for forming a compressive strained channel, according to an embodiment of the present disclosure.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

It is understood that although the disclosed embodiments include a detailed description of an exemplary VFET architecture, implementation of the teachings recited herein are not limited to the particular FET architecture described herein. Rather, embodiments of the present invention are capable of being implemented in conjunction with any other type of FET device now known or later developed.

VFETs have been pursued as a potential device option for scaling complementary metal-oxide semiconductors (CMOS) to the 3 nanometer (nm) node and beyond. As opposed to planar CMOS devices, VFETs are oriented vertically with a vertical fin or nanowire that extends upward from the substrate. The fin or nanowire forms the channel region of the transistor. A source region and a drain region are situated in electrical contact with the top and bottom ends of the channel region, while the gate is disposed on one or more of the fin or nanowire sidewalls. Thus, in VFETs the direction of the current flow between the source and drain regions is normal to the main surface of the substrate.

In general, in a p-type FET, compressive strain improves mobility of the holes, allowing for better performance of the VFET. In an n-type VFET, it is tensile strain that improves mobility of the electrons, allowing for better performance of the VFET. Strained channel techniques can be used to improve mobility, resulting in better chip performance and lower energy consumption. Achieving the strain on the channel can be accomplished through lattice mismatch of silicon and silicon germanium, which causes strain when they are deposited on each other. As semiconductor devices continue to scale downward in size, structural and space limitations can hinder inducing a strain in the channel region along a vertical direction in VFETs.

Therefore, embodiments of the present disclosure describe a semiconductor structure, and a method of making the same, in which a stress liner is embedded within an epitaxial silicon layer for providing a strained channel and improving carrier mobility. More specifically, a channel fin structure including a compressive stressed silicon nitride liner surrounded by the epitaxial silicon layer is formed for providing a tensile strain on a vertical direction in n-type VFETs. Additionally or alternatively, a channel fin structure including a tensile stressed silicon nitride liner surrounded by the epitaxial silicon layer is formed for providing a compressive strain on a vertical direction in p-type VFETs.

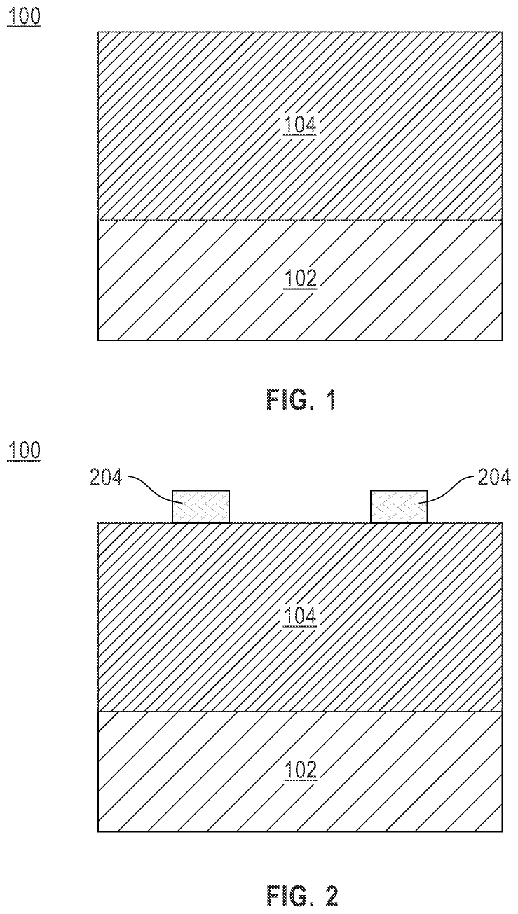

Embodiments by which the VFET device with strained channel can be formed is described in detailed below by referring to the accompanying drawings in FIGS. 1-11B.

Referring now to FIG. 1, a cross-sectional view of a semiconductor structure 100 at an intermediate step during a semiconductor manufacturing process is shown, according to an embodiment of the present disclosure. Particularly, in the depicted example, the semiconductor structure 100 is shown after forming a first sacrificial semiconductor layer 104 on a substrate 102. The term sacrificial, as used herein, means a layer or other structure, that is (or a part thereof is) removed before completion of the final device.

According to an embodiment, the substrate 102 may be, for example, a bulk substrate, which may be made from any of several known semiconductor materials such as, for example, silicon, germanium, silicon-germanium alloy, and compound (e.g. III-V and II-VI) semiconductor materials. Non-limiting examples of compound semiconductor materials include gallium arsenide, indium arsenide, and indium phosphide, or indium gallium phosphide. Typically, the substrate 102 may be approximately, but is not limited to, several hundred microns thick. In other embodiments, the substrate 102 may be a layered semiconductor such as a silicon-on-insulator or SiGe-on-insulator, where a buried insulator layer, separates a base substrate from a top semiconductor layer.

With continued reference to FIG. 1, the first sacrificial semiconductor layer 104, is formed on the substrate 102 using an epitaxial growth process. For instance, in the described embodiment, the first sacrificial semiconductor layer 104 is formed by epitaxially growing a layer of silicon germanium (SiGe) with a germanium concentration varying from approximately 10 atomic percent to approximately 50 atomic percent. In an exemplary embodiment, the first sacrificial semiconductor layer 104 can be grown to a thickness varying from approximately 20 nm to approximately 100 nm, although other thicknesses are within the contemplated scope of the invention. The higher concentration of germanium atoms in the first sacrificial semiconductor layer 104 allows the first sacrificial semiconductor layer 104 to be removed selectively to the substrate 102 and subsequently formed semiconductor layers, as will be described in detail below.

In general, the first sacrificial semiconductor layer 104 can be formed by epitaxial growth by using the substrate 102 as the seed layer. Terms such as “epitaxial growth and/or deposition” and “epitaxially formed and/or grown” refer to the growth of a semiconductor material on a deposition surface of a semiconductor material, in which the semiconductor material being grown has the same or substantially similar crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same or substantially similar crystalline characteristics as the deposition surface on which it is formed. For example, an epitaxial semiconductor material deposited on a {100} crystal surface will take on a {100} orientation. In some embodiments, epitaxial growth and/or deposition processes are selective to forming on a semiconductor surface, and do not deposit material on dielectric surfaces, such as silicon dioxide or silicon nitride surfaces.

Non-limiting examples of various epitaxial growth processes include rapid thermal chemical vapor deposition (RTCVD), low-energy plasma deposition (LEPD), ultra-high vacuum chemical vapor deposition (UHVCVD), atmospheric pressure chemical vapor deposition (APCVD), metalorganic chemical vapor deposition (MOCVD), low-pressure chemical vapor deposition (LPCVD), limited reaction processing CVD (LRPCVD), and molecular beam epitaxy (MBE). The temperature for an epitaxial deposition process can range from 500° C. to 900° C. Although higher temperatures typically results in faster deposition, the faster deposition may result in crystal defects and film cracking.

A number of different precursors may be used for the first sacrificial semiconductor layer 104. In some embodiments, a gas source for the deposition of epitaxial semiconductor material includes a silicon containing gas source, a germanium containing gas source, or a combination thereof. For example, an epitaxial silicon layer may be deposited from a silicon gas source including, but not necessarily limited to, silane, disilane, trisilane, tetrasilane, hexachlorodisilane, tetrachlorosilane, dichlorosilane, trichlorosilane, and combinations thereof. An epitaxial germanium layer can be deposited from a germanium gas source including, but not necessarily limited to, germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, helium and argon can be used.

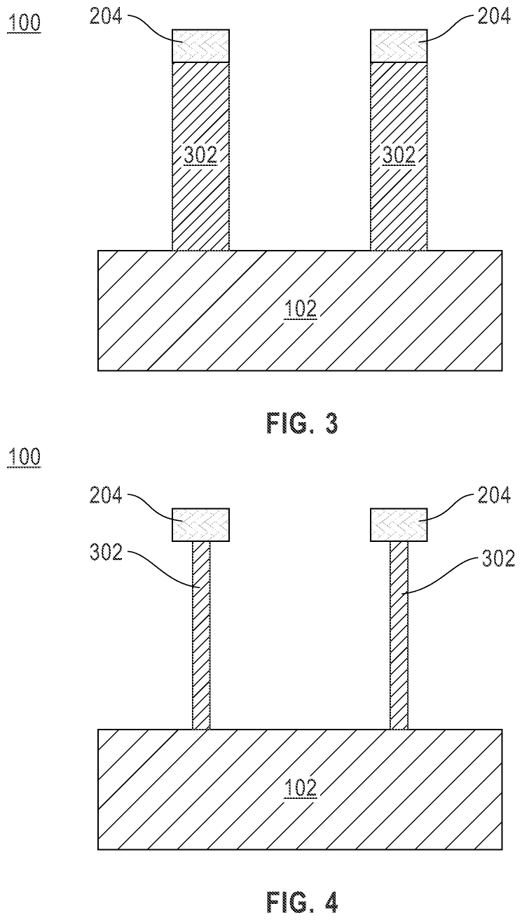

Referring now to FIG. 2 and FIG. 3 simultaneously, cross-sectional views of the semiconductor structure 100 are shown after forming a hardmask layer 204 and patterning sacrificial channel fins 302, according to an embodiment of the present disclosure.

The hardmask layer 204 is formed over the first sacrificial semiconductor layer 104 by depositing a hard mask material using, for example, chemical vapor deposition (CVD), plasma enhanced CVD (PECVD) or any suitable technique for dielectric deposition. In one or more embodiments, the hardmask layer 204 may be formed of silicon nitride (SiN), although other suitable materials such as silicon oxide (SiO_{X}), silicon dioxide (SiO₂) and silicon oxynitride (SiON) may be used. The hardmask layer 204 may have a height or vertical thickness ranging between approximately 20 nm to approximately 100 nm, although other heights above or below this range may be used as required for a particular application.

The hardmask layer 204 may be initially formed over an entire top surface of the first sacrificial semiconductor layer 104, followed by patterning using any suitable technique. In one or more embodiments, a photolithographic patterning is conducted on the deposited hardmask layer 204 to form a plurality of individual fin hardmasks. As shown in FIG. 3, each of the sacrificial channel fins 302 is topped by a hardmask layer 204. The sacrificial channel fins 302 may be formed using sidewall image transfer (SIT) or other suitable techniques.

Each of the sacrificial channel fins 302 may have a width or horizontal thickness ranging from approximately 5 nanometers (nm) to approximately 20 nm, although other widths above or below this range may be used as desired for a particular application. Each of the sacrificial channel fins 302 may have a height or vertical thickness ranging from approximately 20 nm to approximately 100 nm, although other heights above or below this range may also be considered. A spacing or distance between adjacent sacrificial channel fins 302 may range between approximately 20 nm to approximately 100 nm, although other distances above or below this range may be used as desired for a particular application.

It should be noted that some elements and/or features of the semiconductor structure 100 are illustrated in the figures but not described in detail in order to avoid unnecessarily obscuring the presented embodiments. For illustration purposes only, without intent of limitation, only two sacrificial channel fins 302 are depicted in the figure. As may be understood by those skilled in the art, any number of sacrificial channel fins 302 can be formed in the semiconductor structure 100 as required for design purposes.

Referring now to FIG. 4, a cross-sectional view of the semiconductor structure 100 is shown after thinning of the sacrificial channel fins 302, according to an embodiment of the present disclosure.

In the depicted embodiment, a width dimension of the sacrificial channel fins 302 is reduced (or thinned) to create an undercut underneath the hardmask layer 204, as depicted in the figure. Non-limiting examples of etching techniques for reducing the width or trimming the sacrificial channel fins 302 may include at least one of wet etching, dry etching and oxide removal. After the thinning process, each of the sacrificial channel fins 302 may have a width or horizontal thickness ranging from approximately 2 nm to approximately 10 nm.

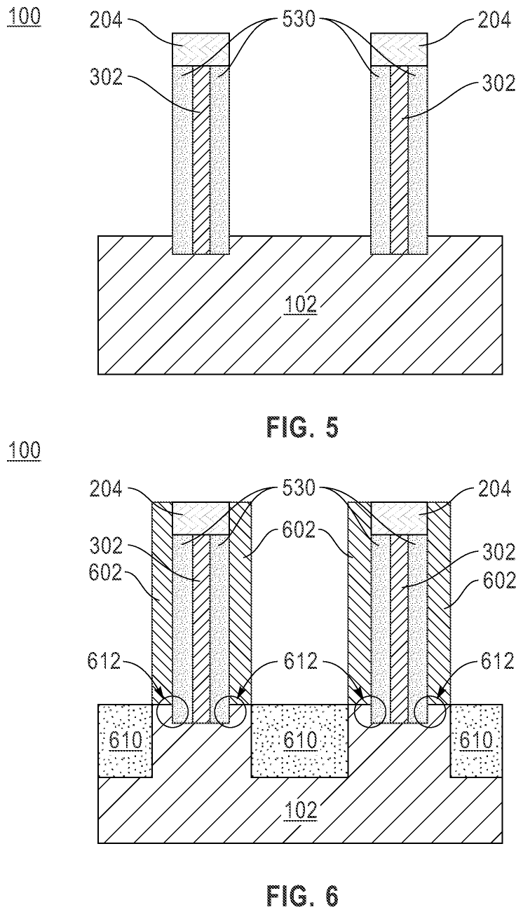

Referring now to FIG. 5, a cross-sectional view of the semiconductor structure 100 is shown after forming a semiconductor channel layer 530 along sidewalls of the sacrificial channel fins 302, according to an embodiment of the present disclosure.

The semiconductor channel layer 530 may be formed off the trimmed sacrificial channel fins 302 by epitaxial growth of a silicon (Si) layer. In this embodiment, the epitaxially grown semiconductor channel layer 530 formed along sidewalls of the sacrificial channel fins 302 provide the channel region of the semiconductor structure 100. It should be noted that the (epitaxial) process used to form the semiconductor channel layer 530 is similar to the process of forming the first sacrificial semiconductor layer 104 (FIG. 2) described above. In an exemplary embodiment, the (Si) semiconductor channel layer 530 may be grown to a thickness varying from approximately 2 nm to approximately 5 nm, although thicknesses above or below this range may also be used.

Referring now to FIG. 6, a cross-sectional view of the semiconductor structure 100 is shown after forming a sacrificial fin spacer 602, bottom source/drain regions 610 and bottom junctions 612, according to an embodiment of the present disclosure.

More specifically, the sacrificial fin spacer 602 may be conformally deposited above and in direct contact with the substrate 102 and along sidewalls of the semiconductor channel layer 530 and hardmask layer 204. The sacrificial fin spacer 602 may function as a protective barrier to preserve the semiconductor channel layer 530 during subsequent manufacturing steps.

The sacrificial fin spacer 602 may include a dielectric material such as silicon oxide, silicon nitride, silicon oxynitride, a low-k material, or any combination thereof. The sacrificial fin spacer 602 may be formed by any suitable deposition method known in the art. Typically, the sacrificial fin spacer 602 may have a thickness ranging from approximately 2 nm to approximately 10 nm, and ranges therebetween.

Portions of the sacrificial fin spacer 602 parallel to the substrate 102 are removed from the semiconductor structure 100, while remaining (vertical) portions are located on opposite sidewalls of the semiconductor channel layer 530 and hardmask layer 204, as depicted in the figure. For example, a top down reactive ion etching (RIE) process, typically known as spacer RIE, can be conducted to remove horizontal portions of the sacrificial fin spacer 602.

With continued reference to FIG. 6, the substrate 102 can be recessed to form bottom source/drain regions 610. Any suitable etching technique may be used to recess the substrate 102. For example, a top down RIE process can be used to recess the substrate 102. In one or more embodiments, the bottom source/drain regions 610 can be formed by a bottom-up epitaxial growth processes. In some embodiments, the bottom source/drain regions 610 can be grown until the height of the epitaxial material substantially fills the recessed substrate 102 for creating the necessary junctions of the semiconductor device (e.g., bottom junctions 612). In other embodiments, the bottom source/drain regions 610 may have a height or vertical thickness ranging from approximately 20 nm to approximately 50 nm. Virtually all semiconductor transistors are based on the formation of junctions. Junctions are capable of both blocking current and allowing it to flow, depending on an applied bias. Junctions are typically formed by placing two semiconductor regions with opposite polarities into contact with one another. The most common junction is the p-n junction, which consists of a contact between a p-type piece of silicon, rich in holes, and an n-type piece of silicon, rich in electrons. N-type and p-type FETs are formed by implanting different types of dopants to selected regions of the device to form the necessary junction(s).

In an exemplary embodiment, the epitaxially grown bottom source/drain regions 610 can be in-situ doped, meaning dopants are incorporated into the epitaxy film during the epitaxy process. Other alternative doping techniques can be used, including but not limited to, for example, ion implantation, gas phase doping, plasma doping, plasma immersion ion implantation, cluster doping, infusion doping, liquid phase doping, solid phase doping, etc., and dopants may include p-type or n-type dopants.

In embodiments in which the semiconductor structure 100 is a p-FET device, p-type dopants can be selected from a group consisting of boron (B), gallium (Ga), indium (In), and thallium (Tl) at various concentrations. In a non-limiting example, a p-type dopant concentration range may be 2×10²⁰/cm³ to 3×10²¹/cm³. In such embodiments, the bottom source/drain regions 610 may include, for example, boron doped SiGe. In embodiments in which the semiconductor structure 100 is a n-FET device, n-type dopants can be selected from a group consisting of phosphorus (P), arsenic (As) and antimony (Sb). In a non-limiting example, an n-type dopant concentration range may be 2×10²⁰/cm³ to 3×10²¹/cm³. In such embodiments, the bottom source/drain regions 610 may include, for example, phosphorous doped silicon.

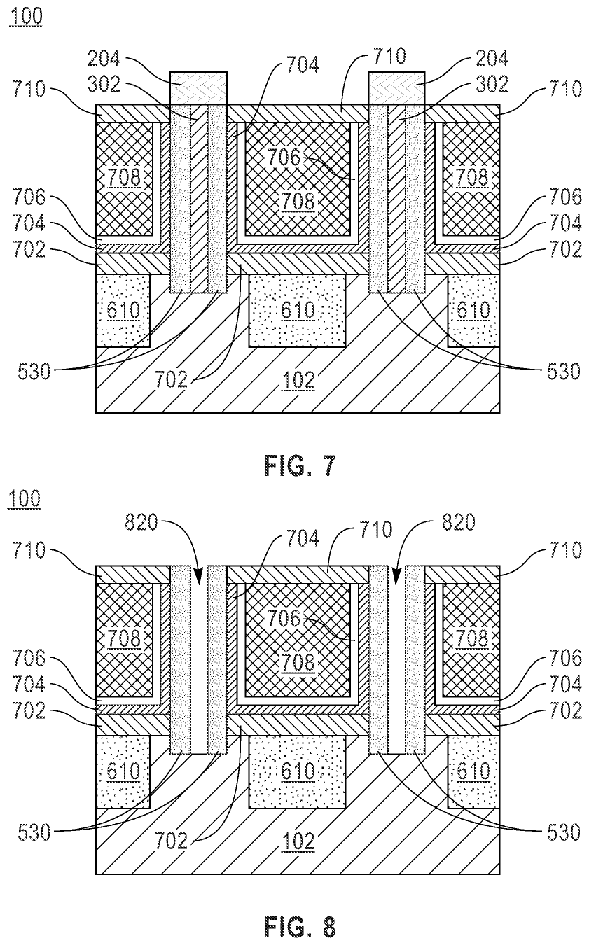

Referring now to FIG. 7, a cross-sectional view of the semiconductor structure 100 is shown after forming a bottom spacer 702, a high-k material 704, a workfunction metal 706, a gate material 708, and a top spacer 710, according to an embodiment of the present disclosure.

At this step of the manufacturing processing, known processing techniques have been conducted on the semiconductor structure 100 to form the bottom spacer 702, high-k material 704, workfunction metal 706, gate material 708 and top spacer 710 as shown in the figure. The bottom spacer 702 is disposed above top surfaces of the source/drain regions 610 and bottom sidewalls of the semiconductor channel layer 530 using non-conformal deposition and etch-back processing (e.g., physical vapor deposition (PVD), high density plasma (HDP) deposition, etc.). Non-limiting examples of materials for forming the bottom spacer 702 may include SiO₂, SiN, silicon carbide oxide (SiCO), silicon boron carbide nitride (SiBCN) and/or other like materials. The bottom spacer 702 may have a (vertical) thickness ranging from approximately 2 nm to approximately 10 nm, although other thicknesses above or below this range may be used as desired for a particular application.

Atop the bottom spacer 702 is the high-k material 704. As depicted in the figure, the high-k material 704 is disposed along a (central) portion of the semiconductor channel layer 530 sidewalls that is not covered by the bottom spacer 702 and top spacer 710. The high-k material 704 can be formed using any suitable deposition method known in the art, including, for example, CVD, plasma-assisted CVD, atomic layer deposition (ALD), evaporation, reactive sputtering, chemical solution deposition or other like deposition processes. Many different types of materials can be used as the high-k material including, but not limited to, HfO₂ (hafnium oxide), ZrO₂ (zirconium dioxide), hafnium zirconium oxide Al₂O₃ (aluminum oxide), and Ta₂O₅ (tantalum pentoxide). A thickness of the high-k material 704 may vary, but typically may have a thickness ranging from approximately 1 nm to approximately 3 nm.

The workfunction metal 706 is formed above the high-k material 704. In embodiments in which the semiconductor structure 100 includes a p-FET device, the workfunction metal 706 may include a p-type work function metal deposited using, for example, deposition techniques including, but not limited to, CVD, PECVD, RFCVD, PVD, ALD, MLD, MBD, PLD, LSMCD, sputtering, and/or plating. The p-type work function metal forming the workfunction metal 706 may include, for example, titanium nitride (TiN), tantalum nitride (TaN) or ruthenium (Ru). A thickness of the workfunction metal 706 may vary, but typically may have a thickness ranging from approximately 2 nm to approximately 10 nm. In embodiments in which the semiconductor structure 100 includes an n-FET device, the workfunction metal 706 may include an n-type work function metal. The n-type work function metal may include, for example, TiN, titanium aluminum nitride (TiAlN), titanium aluminum carbon nitride (TiAlCN), titanium carbide (TiC), titanium aluminum carbide (TiAlC), tantalum aluminum carbide (TaAlC), tantalum aluminum carbon nitride (TaAlCN) or lanthanum (La) doped TiN, TaN.

Subsequently, the gate material 708 is formed using standard deposition processes. In some embodiments, the gate material 708 can be composed of a tungsten-based material or a polysilicon material. Other materials can also be used to form the gate material 708. As can be observed in the figure, uppermost surfaces of the high-k material 704, workfunction metal 706, and gate material 708 are substantially coplanar.

With continued reference to FIG. 7, the top spacer 710 can be conformally deposited above and in direct contact with the uppermost (coplanar) surfaces of the high-k material 704, workfunction metal 706, and gate material 708 and along top sidewalls of the semiconductor channel layer 530. In this embodiment, the top spacer 710 may be deposited using, for example, CVD, PECVD, RFCVD, PVD, ALD, MLD, MBD, PLD, LSMCD, sputtering, and/or plating. Non-limiting examples of materials forming the top spacer 710 may include silicon nitride (SiN), silicon boron nitride (SiBN), siliconborocarbonitride (SiBCN), or silicon oxycarbonitride (SiOCN). Any suitable etching technique (e.g., RIE) may be used to remove the top spacer 710 from top surfaces of the semiconductor structure 100, particularly from the hardmask layer 204, as depicted in the figure. The top spacer 710 may have a (vertical) thickness ranging from approximately 2 nm to approximately 10 nm, although other thicknesses above or below this range may be used as desired for a particular application.

Referring now to FIG. 8, a cross-sectional view of the semiconductor structure 100 is shown after removing the hardmask layer 204 and the sacrificial channel fins 302 shown in FIG. 7, according to an embodiment of the present disclosure.

In this embodiment, the hardmask layer 204 and the sacrificial channel fins 302 can be selectively removed from the semiconductor structure using any suitable etching technique. Non-limiting examples of etching processes to remove the hardmask layer 204 and the sacrificial channel fins 302 may include dry methods such as reactive ion etch (RIE), or wet removal. As depicted in the figure, removal of the sacrificial channel fins 302 creates an opening 820 within the semiconductor channel layer 530.

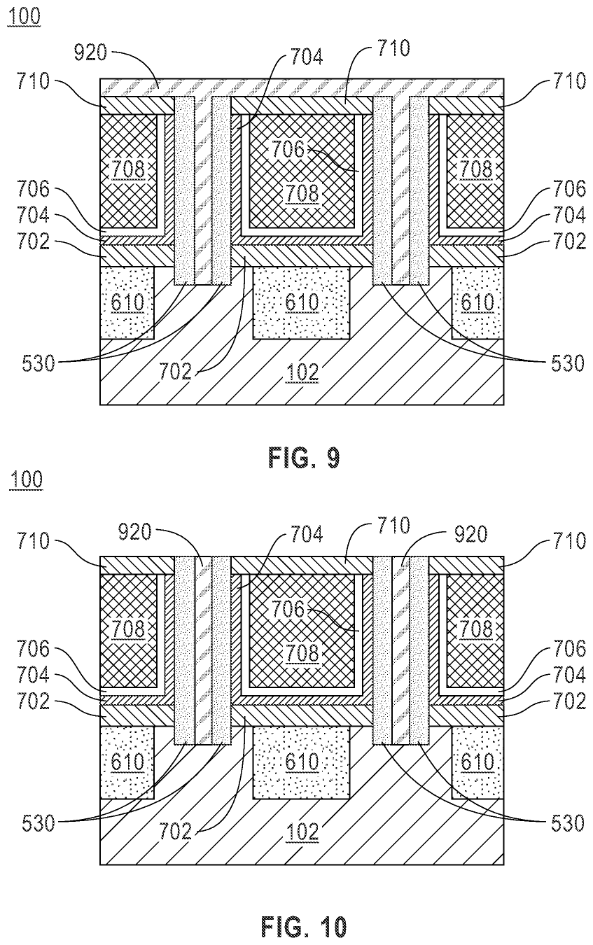

Referring now to FIG. 9 and FIG. 10 simultaneously, cross-sectional views of the semiconductor structure 100 are shown after depositing and etching back a stress liner 920, according to an embodiment of the present disclosure.

The stress liner 920 can be conformally deposited on the semiconductor structure 100 using standard deposition processes including, for example, ALD or CVD. The stress liner 920 substantially fills the openings 820 (FIG. 8). As depicted in FIG. 10, an etch-back process is conducted on the semiconductor structure 100 to remove the stress liner 920 from horizontal top surfaces, as depicted in the figure. The etch-back process may include, for example, a dry etch or wet etch technique. After the etch back process uppermost surfaces of the stress liner 920, semiconductor channel layer 530 and top spacer 710 are substantially coplanar.

According to an embodiment, the stress liner 920 may be composed of a nitride material, specifically silicon nitride (SiN). It should be noted that in embodiments in which the semiconductor structure 100 is a p-FET device, the stress liner 920 includes a tensile stressed SiN material for providing a compressive strained channel, while in embodiments in which the semiconductor structure 100 is an n-FET device, the stress liner 920 includes a compressive stressed SiN material for providing a tensile strained channel.

Thus, the stress liner 920 surrounded or encapsulated by the semiconductor channel layer 530 provides a channel fin structure extending vertically from the substrate 102. In one or more embodiments, the strain polarity/strain level of the deposited stress liner 920 can be controlled to induce an uniaxial strain along a vertical direction of the channel fin structure as needed to satisfy design requirements. Accordingly, a compressive stressed liner 902 can be formed for providing a tensile strained channel, or a tensile stressed liner 902 can be formed for providing a compressive strained channel, as explained above.

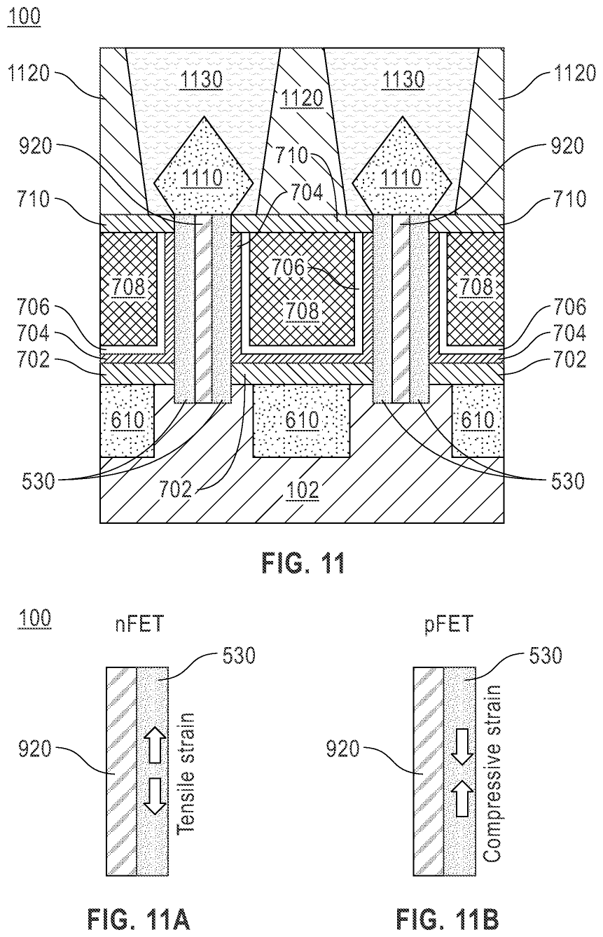

Referring now to FIG. 11, a cross-sectional view of the semiconductor structure 100 is shown after forming top source/drain regions 1110 and metal contacts 1130, according to an embodiment of the present disclosure.

At this point of the manufacturing process, top source/drain regions 1110 can be formed off the exposed portion of the semiconductor channel layer 530 following steps similar to the ones described above with respect to the bottom source/drain regions 610. As may be known by those skilled in the art, the diamond shape observed in each of the top source/drain regions 1110 may be a consequence of the different growth rates during the epitaxial deposition process inherent to each crystallographic orientation plane of the material forming the top source/drain regions 1110. In other embodiments, the top source/drain regions 1110 may have a shape other than the diamond shape depicted in FIG. 11. It should be noted that details of previously described features and techniques have been omitted to avoid unnecessarily obscuring the presented embodiments.

An interlevel dielectric filling layer 1120 can be subsequently formed to fill voids within the semiconductor structure 100. The interlevel dielectric filling layer 1120 may be formed by, for example, chemical vapor deposition (CVD) of a dielectric material. Non-limiting examples of dielectric materials to form the interlevel dielectric filling layer 1120 include, for example, silicon oxide, silicon nitride, hydrogenated silicon carbon oxide, silicon based low-k dielectrics, flowable oxides, porous dielectrics, or organic dielectrics including porous organic dielectrics. Typically, after deposition of the interlevel dielectric filling layer 1120, a chemical mechanical polishing (CMP) process is conducted on the semiconductor structure 100.

Contact trenches (not shown) may be subsequently formed in the interlevel dielectric filling layer 1120 by any photolithographic patterning process including, for example, an anisotropic etching process or plasma etching. Metal contacts 1130 (i.e., top source/drain contacts) can then be formed within the contact trenches (not shown) using conventional techniques well-known to those skilled in the art. It should be noted that, although not depicted in the figure, bottom source/drain contacts and a gate contacts can also be formed in the semiconductor structure 100.

Thus, the previously described embodiments provide a semiconductor structure 100, and a method of making the same, having a strained channel region along a vertical direction of the semiconductor device, the strained channel region being achieved by forming a stress liner (e.g., stress liner 920) embedded within an epitaxially grown silicon channel layer (e.g., semiconductor channel layer 530). Based on a polarity of the semiconductor structure 100, the embedded stress liner may include a compressive stressed liner for forming a tensile strained channel (n-FETs) or a tensile stressed liner for forming a compressive strained channel (p-FETs), as illustrated in FIG. 11A and FIG. 11B, respectively.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Spatially relative terms, such as “inner,” “outer,” “beneath,” “below,” “lower,” “above,” “upper,” “top,” “bottom,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90 degrees or at other orientations) and the spatially relative descriptors used herein interpreted accordingly.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a channel fin structure extending vertically from a substrate, the channel fin structure including a stress liner embedded within a semiconductor channel layer for inducing an uniaxial strain along a vertical direction of the channel fin structure;
a high-k material disposed along sidewalls of the semiconductor channel layer;
a workfunction metal disposed above the high-k material; and
a gate material disposed above the workfunction metal.

2. The semiconductor structure of claim 1, wherein the stress liner comprises a compressive stressed silicon nitride material for providing a tensile strain on the channel fin structure.

3. The semiconductor structure of claim 1, wherein the stress liner comprises a tensile stressed silicon nitride material for providing a compressive strain on the channel fin structure.

4. The semiconductor structure of claim 1, wherein the semiconductor channel layer comprises a layer of epitaxially grown silicon.

5. The semiconductor structure of claim 1, further comprising:
a top source/drain region located above a top portion of the channel fin structure; and
a bottom source/drain region within the substrate and adjacent to a bottom portion of the channel fin structure.

6. The semiconductor structure of claim 5, further comprising:
a top spacer on opposite sidewalls of a top portion of the channel fin structure for separating the high-k material, the workfunction metal and the gate material from the top source/drain region; and
a bottom spacer on opposite sidewalls of a bottom portion of the channel fin structure for separating the high-k material, the workfunction metal and the gate material from the bottom source/drain region.

7. The semiconductor structure of claim 6, further comprising:
a top source/drain contact extending through a interlevel dielectric filling layer until an uppermost surface of the top source/drain region, the interlevel dielectric filling layer disposed above the top spacer.

8. A method of forming a semiconductor structure, comprising:
forming a channel fin structure extending vertically from a substrate, the channel fin structure including a stress liner surrounded by a semiconductor channel layer;
forming a high-k material disposed along sidewalls of the semiconductor channel layer;
forming a workfunction metal disposed above the high-k material; and
forming a gate material disposed above the workfunction metal.

9. The method of claim 8, wherein the stress liner comprises a compressive stressed silicon nitride material for providing a tensile strain on the channel fin structure.

10. The method of claim 8, wherein the stress liner comprises a tensile stressed silicon nitride material for providing a compressive strain on the channel fin structure.

11. The method of claim 8, wherein forming the channel fin structure further comprises:
epitaxially growing a sacrificial semiconductor layer above the substrate;
patterning the sacrificial semiconductor layer to from a sacrificial channel fin;
thinning the sacrificial channel fin; and
epitaxially growing the semiconductor channel layer on sidewalls of the sacrificial channel fin.

12. The method of claim 11, wherein the sacrificial semiconductor layer comprises silicon-germanium.

13. The method of claim 11, wherein the semiconductor channel layer comprises silicon.

14. The method of claim 11, further comprising:
forming a fin spacer along the sidewalls of the semiconductor channel layer.

15. The method of claim 14, further comprising:
forming a bottom source/drain region within the substrate and adjacent to a bottom portion of the channel fin structure;
removing the fin spacer;
forming a bottom spacer on opposite sidewalls of a bottom portion of the channel fin structure for separating the high-k material, the workfunction metal and the gate material from the bottom source/drain region; and
forming a top spacer on opposite sidewalls of a top portion of the channel fin structure.

16. The method of claim 15, further comprising:
selectively removing the sacrificial channel fin, wherein removing the sacrificial channel fin forms an opening within the semiconductor channel layer; and
depositing the stress liner within the opening.

17. The method of claim 16, further comprising:
forming a top source/drain region located above the top portion of the channel fin structure, wherein the top spacer separates the high-k material, the workfunction metal and the gate material from the top source/drain region.

18. The method of claim 17, further comprising:
forming an interlevel dielectric filling layer above the top spacer and surrounding the top source/drain region; and
patterning the interlevel dielectric filling layer to form a contact trench.

19. The method of claim 18, further comprising:
forming a top source/drain contact within the contact trench, the top source/drain contact extending through the interlevel dielectric filling layer until an uppermost surface of the top source/drain region.

20. The method of claim 8, wherein the stress liner induces an uniaxial strain along a vertical direction of the channel fin structure.
